(19) United States
(12) Patent Application Publication
(10) Pub. No.: US 2005/0092255 A1
(43) Pub. Date: May 5, 2005

(54) Edge-contact wafer holder for CMP load/unload station

(75) Inventors: Feng-Jung Chang, Tainan (TW); Poyueh Tsai, Hsin-Chu (TW); Feng-Yu Kuo, Kaohsiung City (TW); Wei-Kung Tsai, Ping-Tung (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co. Ltd.

(21) Appl. No.: 10/701,804

(22) Filed: Nov. 4, 2003

(51) Int. Cl. C23C 16/00

(52) U.S. Cl. 118/728

(57) ABSTRACT

An edge-contact wafer holder which is suitable for holding wafers as the wafers are loaded onto and unloaded from a processing tool such as a CMP (chemical mechanical planarization) apparatus, for example. The edge-contact wafer holder includes a typically ring-shaped holder body which is mounted typically on a load cup on a HCLU (Head Clean Load/Unload) station of a CMP apparatus and supports each individual wafer at or near the wafer edge. Multiple guide pins may extend upwardly from the holder body to guide each wafer onto the holder body as the wafer is lowered in place onto the holder body.

### FIELD OF THE INVENTION

The present invention relates to chemical mechanical polishing apparatus for polishing semiconductor wafer substrates. More particularly, the present invention relates to a new and improved wafer holder for an HCLU (Head Clean Load/Unload) station and which prevents or reduces particle contamination of a semiconductor wafer by contacting the edges of the wafer during loading and unloading of the wafer to and from a CMP apparatus.

### BACKGROUND OF THE INVENTION

In the fabrication of semiconductor devices from a silicon wafer, a variety of semiconductor processing equipment and tools are utilized. One of these processing tools is used for polishing thin, flat semiconductor wafers to obtain a planarized surface. A planarized surface is highly desirable on a shadow trench isolation (STI) layer, inter-layer dielectric (ILD) or on an inter-metal dielectric (IMD) layer, copper line (Cu CMP) layer which are frequently used in memory devices. The planarization process is important since it enables the subsequent use of a high- resolution lithographic process to fabricate the next-level circuit. The accuracy of a high resolution lithographic process can be achieved only when the process is carried out on a substantially flat surface. The planarization process is therefore an important processing step in the fabrication of semiconductor devices.

A global planarization process can be carried out by a technique known as chemical mechanical polishing, or CMP. The process has been widely used on ILD or IMD layers in fabricating modern semiconductor devices. A CMP process is performed by using a rotating platen in combination with a pneumatically-actuated polishing head. The process is used primarily for polishing the front surface or the device surface of a semiconductor wafer for achieving planarization and for preparation of the next level processing. A wafer is frequently planarized one or more times during a fabrication process in order for the top surface of the wafer to be as flat as possible. A wafer can be polished in a CMP apparatus by being placed on a carrier and pressed face down on a polishing pad covered with a slurry of colloidal silica or aluminum.

A polishing pad used on a rotating platen is typically constructed in two layers overlying a platen, with a resilient layer as an outer layer of the pad. The layers are typically made of a polymeric material such as polyurethane and may include a filler for controlling the dimensional stability of the layers. A polishing pad is typically made several times the diameter of a wafer in a conventional rotary CMP, while the wafer is kept off-center on the pad in order to prevent polishing of a non-planar surface onto the wafer. The wafer itself is also rotated during the polishing process to prevent polishing of a tapered profile onto the wafer surface. The axis of rotation of the wafer and the axis of rotation of the pad are deliberately not collinear; however, the two axes must be parallel. It is known that uniformity in wafer polishing by a CMP process is a function of pressure, velocity and concentration of the slurry used.

A CMP process is frequently used in the planarization of an ILD or IMD layer on a semiconductor device. Such layers are typically formed of a dielectric material. A most popular dielectric material for such usage is silicon oxide. In a process for polishing a dielectric layer, the goal is to remove topography and yet maintain good uniformity across the entire wafer. The amount of the dielectric material removed is normally between about 5000 A and about 10,000 A. The uniformity requirement for ILD or IMD polishing is very stringent since non-uniform dielectric films lead to poor lithography and resulting window-etching or plug-formation difficulties. The CMP process has also been applied to polishing metals, for instance, in tungsten plug formation and in embedded structures. A metal polishing process involves a polishing chemistry that is significantly different than that required for oxide polishing.

Important components used in CMP processes include an automated rotating polishing platen and a wafer holder, which both exert a pressure on the wafer and rotate the wafer independently of the platen. The polishing or removal of surface layers is accomplished by a polishing slurry consisting mainly of colloidal silica suspended in deionized water or KOH solution. The slurry is frequently fed by an automatic slurry feeding system in order to ensure uniform wetting of the polishing pad and proper delivery and recovery of the slurry. For a high-volume wafer fabrication process, automated wafer loading/unloading and a cassette handler are also included in a CMP apparatus.

As the name implies, a CMP process executes a microscopic action of polishing by both chemical and mechanical means. While the exact mechanism for material removal of an oxide layer is not known, it is hypothesized that the surface layer of silicon oxide is removed by a series of chemical reactions which involve the formation of hydrogen bonds with the oxide surface of both the wafer and the slurry particles in a hydrogenation reaction; the formation of hydrogen bonds between the wafer and the slurry; the formation of molecular bonds between the wafer and the slurry; and finally, the breaking of the oxide bond with the wafer or the slurry surface when the slurry particle moves away from the wafer surface. It is generally recognized that the CMP polishing process is not a mechanical abrasion process of slurry against a wafer surface.

While the CMP process provides a number of advantages over the traditional mechanical abrasion type polishing process, a serious drawback for the CMP process is the difficulty in controlling polishing rates at different locations on a wafer surface. Since the polishing rate applied to a wafer surface is generally proportional to the relative rotational velocity of the polishing pad, the polishing rate at a specific point on the wafer surface depends on the distance from the axis of rotation. In other words, the polishing rate obtained at the edge portion of the wafer that is closest to the rotational axis of the polishing pad is less than the polishing rate obtained at the opposite edge of the wafer. Even though this is compensated for by rotating the wafer surface during the polishing process such that a uniform average polishing rate can be obtained, the wafer surface, in general, is exposed to a variable polishing rate during the CMP process.

Recently, a chemical mechanical polishing method has been developed in which the polishing pad is not moved in a rotational manner but instead, in a linear manner. It is therefore named as a linear chemical mechanical polishing process, in which a polishing pad is moved in a linear manner in relation to a rotating wafer surface. The linear polishing method affords a more uniform polishing rate across a wafer surface throughout a planarization process for the removal of a film layer from the surface of a wafer. One added advantage of the linear CMP system is the simpler construction of the apparatus, and this not only reduces the cost of the apparatus but also reduces the floor space required in a clean room environment.

A typical conventional CMP apparatus 90 is shown in FIG. 1 and includes a base 100; polishing pads 210a, 210b, and 210c provided on the base 100; a head clean load/unload (HCLU) station 360 which includes a load cup 300 for the loading and unloading of wafers (not shown) onto and from, respectively, the polishing pads; and a head rotation unit 400 having multiple polishing pads 410a, 410b, 410c and 410d for holding and fixedly rotating the wafers on the polishing pads.

The three polishing pads 210a, 210b and 210c facilitate simultaneous processing of multiple wafers in a short time. Each of the polishing pads is mounted on a rotatable carousel (not shown). Pad conditioners 211a, 211b and 211c are typically provided on the base 100 and can be swept over the respective polishing pads for conditioning of the polishing pads. Slurry supply arms 212a, 212b and 212c are further provided on the base 100 for supplying slurry to the surfaces of the respective polishing pads.

The polishing heads 410a, 410b, 410c and 410d of the head rotation unit 400 are mounted on respective rotation shafts 420a, 420b, 420c, and 420d which are rotated by a driving mechanism (not shown) inside the frame 401 of the head rotation unit 400. The polishing heads hold respective wafers (not shown) and press the wafers against the top surfaces of the respective polishing pads 210a, 210b and 210c. In this manner, material layers are removed from the respective wafers. The head rotation unit 400 is supported on the base 100 by a rotary bearing 402 during the CMP process.

As shown in FIG. 1A, the load cup 300 includes a pedestal support column 312 that supports a circular pedestal 310 on which the wafers are placed for loading of the wafers onto the polishing pads 210a, 210b and 210c, and unloading of the wafers from the polishing pads. A pedestal film 313 is typically provided on the upper surface of the pedestal 310 for contacting the patterned surface (the surface on which IC devices are fabricated) of each wafer.

Fluid openings 314 extend through the pedestal 310 and pedestal film 313. The bottom surfaces of the polishing heads 410a, 410b, 410c and 410d and the top surface of the pedestal film 313 are washed at the load cup 300 by the ejection of washing fluid through the fluid openings 314.

After prolonged use of the load cup 300, the pedestal film 313 accumulates various contaminants such as sulfur residues and particulate residues that may have a tendency to contaminate or scratch wafers placed on the pedestal film 313. The contaminants and scratches may cause defects such as gate oxide leakage or gate line bridging in the semiconductor devices fabricated on the patterned surface of the wafers, thereby lowering the yield and reliability of the devices. Particle-induced defects related to transfer of contaminants from the pedestal film 313 to the wafer or scratching of the wafer are particularly problematic with regard to 0.13 μm and beyond copper process technology. For this reason, the washing step is very important in the CMP process. However, the washing step is incapable of removing all contaminants from the pedestal film. Accordingly, a new and improved wafer holder is needed which minimizes or avoids contact with the surfaces of a wafer as the wafer is loaded onto and unloaded from a CMP apparatus.

An object of the present invention is to provide a novel wafer holder which minimizes or avoids contact with a wafer surface during loading and unloading of a wafer.

Another object of the present invention is to provide a novel wafer holder which contacts the edge region of a wafer.

Still another object of the present invention is to provide a novel wafer holder which prevents or eliminates contamination of wafers during handling of the wafers.

Yet another object of the present invention is to provide a novel wafer holder which prevents contamination of wafers by handling the wafers at the edge region of each wafer.

A still further object of the present invention is to provide a novel wafer holder which is suitable for loading wafers to and unloading wafers from a CMP apparatus.

A still further object of the present invention is to provide a novel wafer holder which may have a ring-shaped configuration to contact wafers at the edge region of each wafer and prevent contamination of the wafer surfaces.

### SUMMARY OF THE INVENTION

In accordance with these and other objects and advantages, the present invention is generally directed to a novel edge-contact wafer holder which is suitable for holding wafers as they are loaded and unloaded to and from a CMP apparatus, for example. The invention includes a typically ring-shaped holder body which is provided typically on a load cup on a HCLU (Head Clean Load/Unload) station of a CMP apparatus and supports each individual wafer at the wafer edge. Throughout the wafer loading and unloading operation, the wafer holder avoids contact with the patterned surface of the wafer, thus preventing transfer of potential device-contaminating particles or wafer-scratching particles from the wafer holder to the IC devices being fabricated on each wafer.

Multiple guide pins may extend upwardly from the holder body to guide each wafer onto the holder body as the wafer is placed onto the holder body. Typically, at least three guide pins extend upwardly from the holder body in equally-spaced relationship to each other. Preferably, the holder body is ceramic for dimensional stability.

### BRIEF DESCRIPTION OF THE DRAWINGS

The invention will now be described, by way of example, with reference to the accompanying drawings, in which:

FIG. 1 is a perspective view of a typical conventional chemical mechanical polishing apparatus for the simultaneous polishing of multiple wafers;

FIG. 1A is a top perspective view, partially in section, of a conventional pedestal assembly of the CMP apparatus of FIG. 1;

FIG. 2 is a perspective view of an edge-contact wafer holder of the present invention;

FIG. 3 is a top view of the edge-contact wafer holder of FIG. 2, with a wafer (in phantom) supported on the wafer holder;

FIG. 4 is a perspective view of the edge-contact wafer holder, mounted on a load cup of an HCLU (Head Clean Load/Unload) station;

FIG. 5 is a side view of the edge-contact wafer holder, mounted on a load cup of an HCLU station, with a semiconductor wafer supported by the wafer holder;

FIG. 6 is a cross-sectional view of the edge-contact wafer holder, taken along section lines 5-5 in FIG. 3;

FIG. 7 is a bottom view of the edge-contact wafer holder of FIGS. 3 and 4, supporting a wafer;

FIG. 8 is a top view of a CMP apparatus which includes the edge-contact wafer holder of the present invention; and

FIG. 9 is a side view of the load cup of an HCLU station on the CMP apparatus of FIG. 7, illustrating loading and unloading of a semiconductor wafer onto and from, respectively, the edge-contact wafer holder of the present invention.

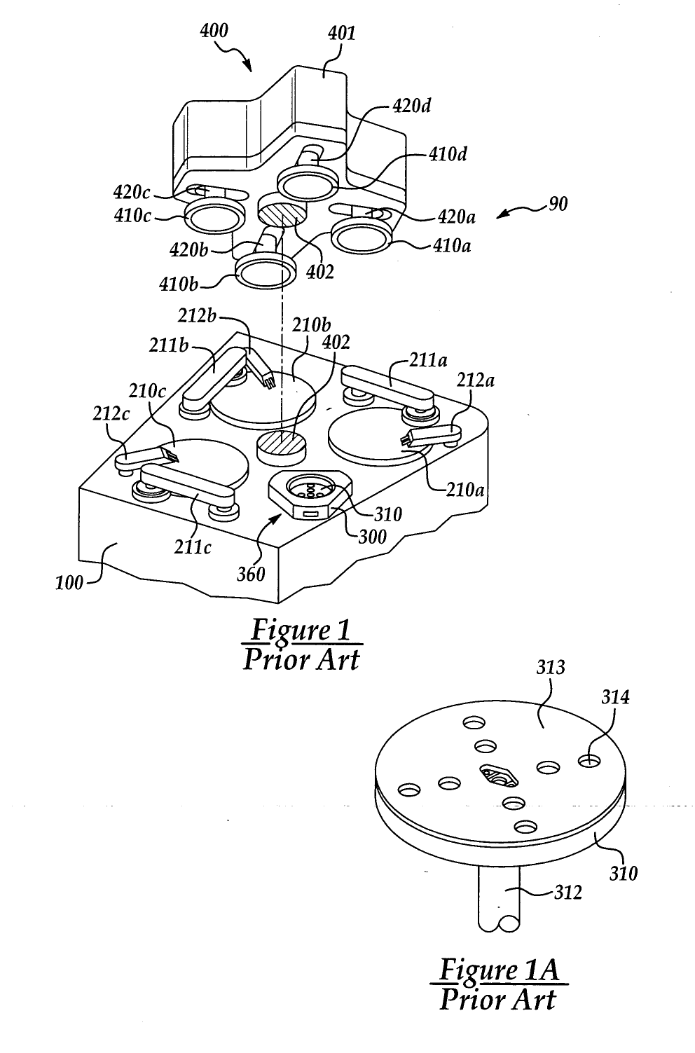

### DETAILED DESCRIPTION OF THE INVENTION

The present invention has particularly beneficial utility in supporting semiconductor wafers to facilitate loading of the wafers onto and unloading of the wafers from a CMP (chemical mechanical planarization) apparatus. However, the invention is not so limited in application, and while references may be made to such CMP apparatus, the invention is more generally applicable to supporting semiconductor wafers to facilitate loading and/or unloading of the wafers to and from other processing apparatus.

The present invention includes a novel edge-contact wafer holder which is suitable for holding wafers as the wafers are loaded onto and unloaded from a processing tool such as a CMP (chemical mechanical planarization) apparatus, for example. The edge-contact wafer holder contacts each wafer along the edge region surrounding the patterned region, rather than the patterned region, of the wafer. Consequently, the patterned region, on which IC devices are fabricated, of the wafer remains untouched throughout the loading and unloading operation, thereby preventing contamination and/or scratching of the patterned region.

The edge-contact wafer holder includes a typically ring-shaped holder body which is mounted typically on a load cup on a HCLU (Head Clean Load/Unload) station of a CMP apparatus and supports each individual wafer at or near the wafer edge. Multiple guide pins may extend upwardly from the holder body to guide each wafer onto the holder body as the wafer is lowered in place onto the holder body. In one embodiment, at least three guide pins extend upwardly from the holder body, typically in equally-spaced relationship to each other. Preferably, the holder body is a ceramic material to impart dimensional stability to the edge-contact wafer holder.

The edge-contact wafer holder of the present invention is capable of reducing the failure rate caused by copper loss-related defects from about 40% to 0%. Furthermore, defects related to sulfur contamination are reduced from about 5% to 0%. This substantial reduction of defects reduces the prevalence of Cu lost defects, open line defects and metal line bridging in the finished IC products.

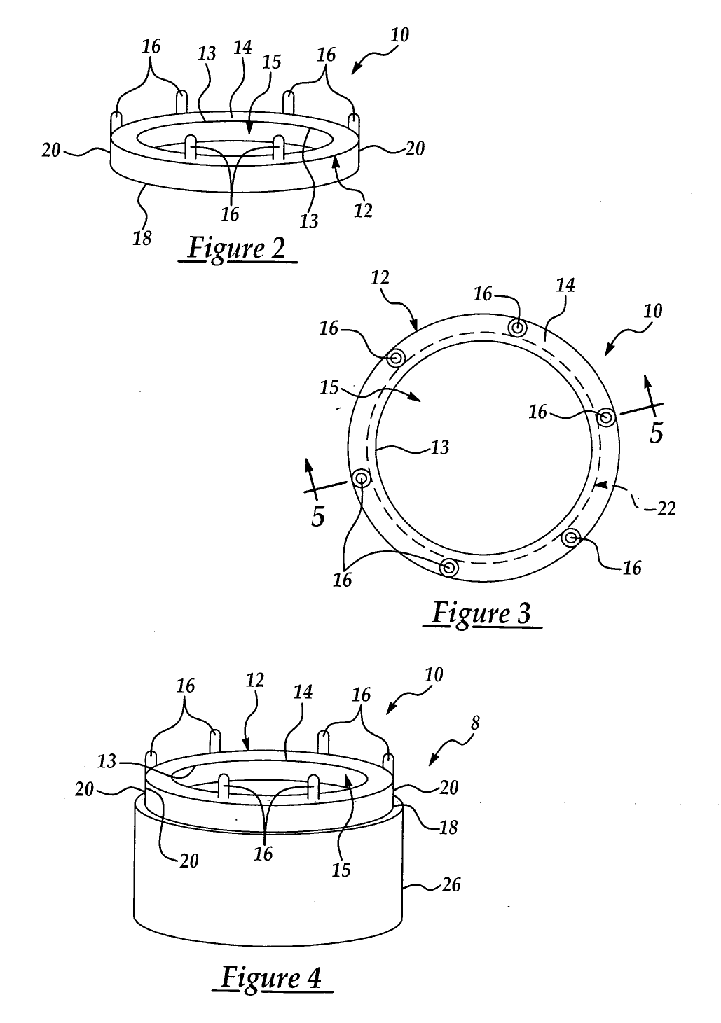

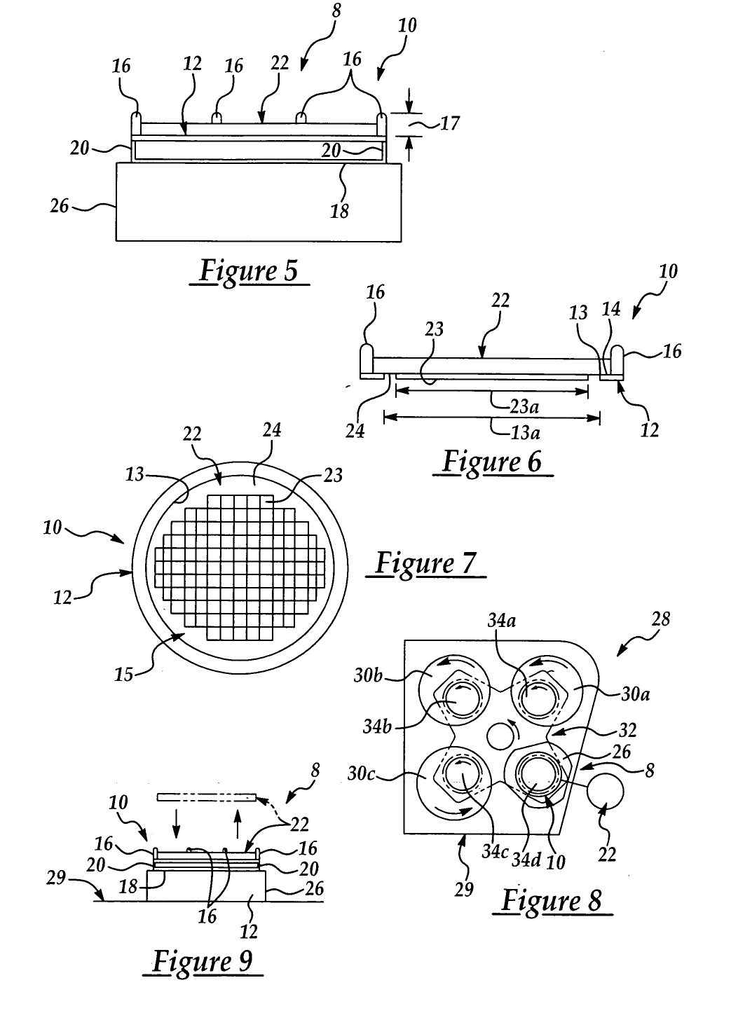

Referring initially to FIGS. 2-7, an illustrative embodiment of the edge-contact wafer holder of the present invention is generally indicated by reference numeral 10. The edge-contact wafer holder 10 includes an annular, typically wire holder frame 18 from which extends multiple support members 20. A ring-shaped holder body 12, having an inner edge 13 that circumscribes a body opening 15, is provided on the upper ends of the support members 20. The holder body 12 is typically a ceramic material. The holder body 12 includes a typically flat, upper support surface which, as shown in FIG. 5, contacts the edge region 24 of a semiconductor wafer 22 when the wafer 22 is supported by the edge-contact wafer holder 10, in application of the edge-contact wafer holder 10 as hereinafter further described.

As shown in FIGS. 6 and 7, the edge region 24 of a semiconductor wafer 22 surrounds a patterned region 23 on which IC devices are fabricated throughout the course of semiconductor fabrication. Typically, the patterned region 23 on each wafer 22 which is to be supported on the edge-contact wafer holder 10 includes a metal layer such as copper which is to be subjected to CMP, as hereinafter further described. When the wafer 22 rests on the holder body 12, the support surface 14 of the holder body 12 does not contact the patterned region 23 and only contacts the edge region 24 of the wafer 22. Therefore, the inner edge 13 of the holder body 12 has a diameter 13a which is greater than the greatest width 23a of the patterned region 23 on the wafer 22, such that the patterned region 23 is exposed through the body opening 15 of the holder body 12, as shown in FIG. 7. Since wafers 22 may vary in diameter, the edge-contact wafer holders 10 can be constructed with holder bodies 12 of various diameters to hold wafers 22 of corresponding sizes.

Multiple guide pins 16 may extend upwardly from the support surface 14 of the holder body 12, typically in generally equally-spaced relationship to each other around the circumference of the holder body 12. Each of the guide pins 16 is typically a ceramic material, but may be fabricated from other materials as well, which is continuous with the support surface 14. As shown in FIG. 6, each guide pin 16 has a guide pin height 17 of typically at least about 3 mm. In a preferred embodiment, at least three guide pins 16 extend upwardly from the support surface 14.

Referring next to FIGS. 6-9, the edge-contact wafer holder 10 is typically mounted on an HCLU (Head Clean Load/Unload) station 8 of a CMP apparatus 28, as shown in FIG. 8. The CMP apparatus 28 typically includes a base 29, on which is mounted a load cup 26 of the HCLU station 8 and a rotatable first polishing pad 30a, second polishing pad 30b and third polishing pad 30c. A head rotation unit 32 is mounted above the base 29 and includes a first polishing head 34a, a second polishing head 34b, a third polishing head 34c and a fourth polishing head 34d.

As shown in FIGS. 4 and 5, the holder frame 18 of the edge-contact wafer holder 10 is mounted on the load cup 26 of the HCLU station 8. The support members 20 therefore space the holder body 12 from the load cup 26. Accordingly, the holder body 12 is properly positioned for the receiving of individual wafers 22 as the wafers 22 wait to be polished using the polishing heads 30a-30c of the CMP apparatus 28, as hereinafter further described.

As illustrated in FIGS. 8 and 9, typical use of the edge-contact wafer holder 10 is as follows. Multiple wafers 22 in a wafer cassette (not shown) are initially transported from an upstream processing station (not shown) to the CMP apparatus 28 for the chemical mechanical planarization typically of a copper layer on the patterned region 23 of the wafer 22. A wafer transfer robot (not shown) individually transfers each wafer 22 from the wafer transfer vehicle (not shown) to the wafer holder 10. With the patterned region 23 on the wafer 22 facing down, the wafer 22 is first positioned directly over the wafer holder 10, as indicated by the phantom lines in FIG. 9, and then lowered to rest on the holder body 12, as indicated by the solid line in FIG. 9. As the wafer 22 is lowered onto the holder body 12, the guide pins 16 guide the wafer 22 into the proper position on the support surface 14 of the holder body 12. Accordingly, as shown in FIG. 6, the support surface 14 contacts only the edge region 24 of the wafer 22, leaving the patterned region 23 exposed through the body opening 15 of the holder body 12.

The wafer 22 is eventually transferred from the wafer holder 10 and attached to the first polishing head 34a of the head rotation unit 32 on the CMP apparatus 28, where the first polishing head 34a rotates the wafer 22 against the first polishing pad 30a. The first polishing head 34a removes material from the patterned region 23 of the wafer 22 typically at a relatively high removal rate. The wafer 22 is then transferred to the second polishing head 34b, which rotates the wafer 22 against the second polishing pad 30a to remove additional material from the patterned region 23, typically at a relatively low removal rate. Next, the wafer 22 is transferred to the third polishing head 34c , which typically rotates the wafer 22 against the third polishing pad 30c to subject the patterned region 23 to an oxide buff step.

After the oxide buff step, the wafer 22 is transferred from the third polishing head 34c back to the wafer holder 10, where the wafer 22 is again placed in the face-down position on the holder body 12, as shown in FIG. 6 and heretofore illustrated with respect to FIG. 9. The wafer 22 is then subjected to a rinsing step in which de-ionized water (not shown) is sprayed from spray nozzles (not shown) inside the load cup 26, through the body opening 15 of the holder body 12 and against the patterned region 23 of the wafer 22. This rinsing step removes from the wafer 22 particles which remain on the patterned region 23 after the CMP process. After the rinsing step, the wafer 22 is removed from the wafer holder 10 and typically transferred to a wafer cassette (not shown) for subsequent processing.

While the preferred embodiments of the invention have been described above, it will be recognized and understood that various modifications can be made in the invention and the appended claims are intended to cover all such modifications which may fall within the spirit and scope of the invention.

1. An edge-contact wafer holder for holding a wafer having a patterned region and an edge region surrounding the patterned region, comprising:
a holder body having a support surface for contacting the edge region of the wafer and a body opening extending through said holder body for exposing the patterned region on the wafer.

2. The edge-contact wafer holder of claim 1 further comprising at least three guide pins extending upwardly from said holder body for guiding the wafer onto said support surface.

3. The edge-contact wafer holder of claim 1 wherein said holder body comprises a ceramic material.

4. The edge-contact wafer holder of claim 3 further comprising at least three guide pins extending upwardly from said holder body for guiding the wafer onto said support surface.

5. The edge-contact wafer holder of claim 1 wherein said holder body has an annular configuration.

6. The edge-contact wafer holder of claim 5 further comprising at least three guide pins extending upwardly from said holder body for guiding the wafer onto said support surface.

7. The edge-contact wafer holder of claim 5 wherein said holder body comprises a ceramic material.

8. The edge-contact wafer holder of claim 7 further comprising at least three guide pins extending upwardly from said holder body for guiding the wafer onto said support surface.

9. An edge-contact wafer holder for holding a wafer having a patterned region and an edge region surrounding the patterned region, comprising:
a holder frame; and
a holder body carried by said holder frame, said holder body having a support surface for contacting the edge region of the wafer and a body opening extending through said holder body for exposing the patterned region on the wafer.

10. The edge-contact wafer holder of claim 9 further comprising at least three guide pins extending upwardly from said holder body for guiding the wafer onto said support surface.

11. The edge-contact wafer holder of claim 9 wherein said holder body comprises a ceramic material.

12. The edge-contact wafer holder of claim 11 further comprising at least three guide pins extending upwardly from said holder body for guiding the wafer onto said support surface.

13. The edge-contact wafer holder of claim 9 wherein said holder body has an annular configuration.

14. The edge-contact wafer holder of claim 13 further comprising at least three guide pins extending upwardly from said holder body for guiding the wafer onto said support surface.

15. The edge-contact wafer holder of claim 13 wherein said holder body comprises a ceramic material.

16. The edge-contact wafer holder of claim 15 further comprising at least three guide pins extending upwardly from said holder body for guiding the wafer onto said support surface.

17. An edge-contact wafer holder for holding a wafer having a patterned region and an edge region surrounding the patterned region, comprising:
a holder frame;
a plurality of support members extending from said holder frame; and
a holder body carried by said plurality of support members, said holder body having a support surface for contacting the edge region of the wafer and a body opening extending through said holder body for exposing the patterned region on the wafer.

18. The edge-contact wafer holder of claim 17 further comprising at least three guide pins extending upwardly from said holder body for guiding the wafer onto said support surface.

19. The edge-contact wafer holder of claim 17 wherein said holder body comprises a ceramic material.

20. The edge-contact wafer holder of claim 17 wherein said holder body has an annular configuration.
